(19) United States
(12) Patent Application Publication
(10) Pub. No.: US 2005/0152113 A1
(43) Pub. Date: Jul. 14, 2005

(54) Motherboard testing mount

(76) Inventor: Tsai-Sheng Pan, Chung Li City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/876,120

(22) Filed: Jun. 24, 2004

(30) Foreign Application Priority Data
Jan. 12, 2004 (TW) 93200483

(51) Int. Cl. H05K 7/20

(52) U.S. Cl. 361/697

(57) ABSTRACT

A mount for motherboard testing. The tool comprises a heat sink and a plurality of protecting ports. The heat sink has an extending portion to avoiding obstruction of access during connection of a microprocessor to a motherboard. Different microprocessors can be replaceably mounted on the extending portion of the heat sink, increasing testing flexibility.

### BACKGROUND

1. Field of the Invention

The present invention relates to a mount, and in particular to a mount suitable for use with different kinds of microprocessors during motherboard testing.

2. Description of the Related Art

As computers become cheaper, the demand for computer becomes larger. Thus, how to make computers cheaper but qualified is an important question for each manufacturer.

Presently, each element in a computer needs to be tested during assembly. In motherboard testing, a motherboard is disposed on an electric jig, and a microprocessor, interface cards and other peripherals are then installed thereon. FIG. 1 shows conventional microprocessor assembly steps for motherboard testing. A microprocessor 13 is first manually installed in a protecting port 14 of an untested motherboard 15 and then a clip 141 of the protecting port 14 is pressed down to fix the microprocessor 14. A heat dissipation module with a heat sink 12 and fan 11 is then mounted on the microprocessor 13 before testing.

In order to protect the microprocessor 13, a large dissipation module is usually used in conventional testing, which may collide with interface cards or other elements, such as capacitors, mounted nearby on the motherboard 15. A heat sink 12 larger than the microprocessor 13 and the protecting port 14 must be installed separately to provide adequate access during repeated manual attachment and detachment. If the microprocessor 13 is mounted under the heat sink 12 and installed in the protecting port 14 at the same time, pins of the microprocessor 13 may easily be bent or damaged, increasing fabrication costs. Allowable testing time in a production line is limited, such that separate assembly steps increase installation time and complexity thereof.

### SUMMARY

Accordingly, embodiments of the invention provide a mount for use with during motherboard testing, enabling microprocessor attachment quicker.

Embodiments of the invention further provide a mount protecting microprocessor pins from bent during repeated attachment and detachment.

An Embodiment of the invention further provides a mount suitable for use with different kinds of microprocessors and motherboards, providing increased flexibility.

Moreover, the embodiment of the invention provide a mount for microprocessors with pins. The mount comprises a heat sink with an extending portion and a protecting port removably disposed thereon. The protecting port comprises a plurality of electrically connected extension pins and holes matching the microprocessor pins.

In the above embodiment, the mount further comprises a frame, fixing the protecting port on the extending portion. The heat sink comprises a plurality of fins and a hollow protecting portion with a fan disposed therein. The fins are radially arranged. The hollow and the extending portion are located on opposite sides of the heat sink. The extending portion comprises cylindrical first part and a removable second part. The second part is rectangular, with the frame removably disposed thereon. The heat sink and the removable second part are aluminum and copper.

The embodiment of the invention provide another mount for two different types of microprocessors. The mount comprises a heat sink with an extending portion, a first protecting port for a first microprocessor and a second protecting port for a second microprocessor. The first and second protecting ports are alternatively disposed on the extending portion.

The first protecting port comprises a plurality of electrically connected first extension pins and first holes, the first holes matching the first pins of the first microprocessor. The second protecting port comprises a plurality of electrically connected second extension pins and second holes, the second holes matching the second pins of the second microprocessor.

Moreover, the mount further comprises a frame, alternately fixing the first or second protecting ports on the extending portion. The heat sink comprises a plurality of fins and a hollow protecting portion with a fan disposed therein. The fins are radially arranged. The hollow and the extending portion are located on opposite sides of the heat sink. The extending portion comprises cylindrical first part and a removable second part. The second part is rectangular, and the frame is removably disposed thereon. The heat sink and the removable second part comprise aluminum and copper.

A detailed description is given in the following embodiments with reference to the accompanying drawings.

### BRIEF DESCRIPTION OF THE DRAWINGS

The embodiment of the invention can be more fully understood by reading the subsequent detailed description and examples with references made to the accompanying drawings which are given by way of illustration only, and thus are not limitation of the invention, and wherein:

FIG. 1 shows conventional microprocessor assembly steps during motherboard testing;

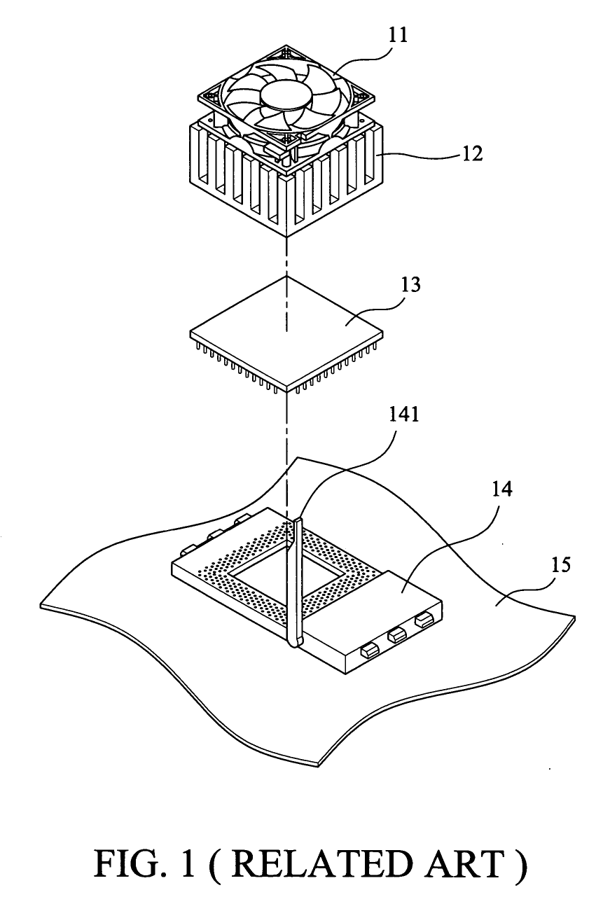

FIG. 2 is an exploded view of a mount for motherboard testing in the embodiment of the invention;

FIG. 3 is a perspective view of the mount for motherboard testing in FIG. 2; and

FIG. 4 is another exploded view of the mount for use with another microprocessor.

### DETAILED DESCRIPTION

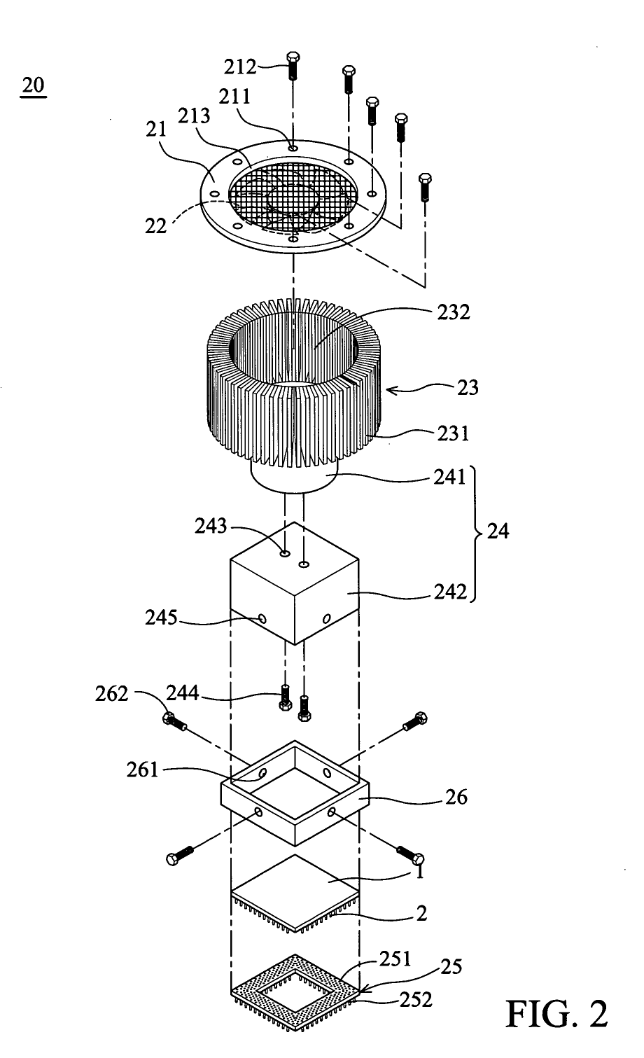

FIG. 2 is an exploded view of a mount for motherboard testing in a first embodiment of the invention. In FIG. 2, a mount 20 of the invention comprises a heat sink 23 with an extending portion 24 and a protecting port 25 removably disposed thereon.

The heat sink 23 in this preferred embodiment is substantially cylindrical. The upper part of the heat sink 23 comprises a central hollow 232 and a plurality of radially arranged fins 231. The central hollow 232 houses for a fan 22 mounted on a cover 21 fastened to the heat sink 23 by the screw 212 passing through the hole 211 thereof, forming a dissipation module. The cover 21 has a central hole covered by a metal mesh 213 acting as both a dissipation passage and safety guard for the fan.

The heat sink 23 of the mount 20 comprises an extending portion 24 corresponding to the central hollow 232. The extending portion 24 comprises a first part 241 and a removable second part 242. The fins 231 and the first part 241 of the extending portion 24 are integrated. The first part 241 is cylindrical, but the removable second part 242 is rectangular to match the profile of a conventional microprocessor 1. The second part 242 of the extending portion 24 is removably fastened to the first part 241 by screws 244 passing through the holes 243 thereof. The heat sink 23 and the removable second part 242 are made of aluminum or copper formed by cutting or extrusion.

In FIG. 2, the mount 20 further comprises a protecting port 25 and a frame 26. The protecting port 25 comprises a plurality of electrically connected extension pins 252 and holes 251 matching the pins 2 of the microprocessor 1. The microprocessor 1 is inserted into the protecting port 25 and protects pins 2 from bending or damaging. Furthermore, the frame 26 is rectangular, matching the profile of the protecting port 25, and fastened to the removable second part 242 by screws 262 passing through the holes 261 and 245. After the frame 26 is fastened to the second part 242 of the extending portion 24, the protecting port 25 housing the microprocessor 1 is pressed into the square hole of the frame 26 and engages therewith.

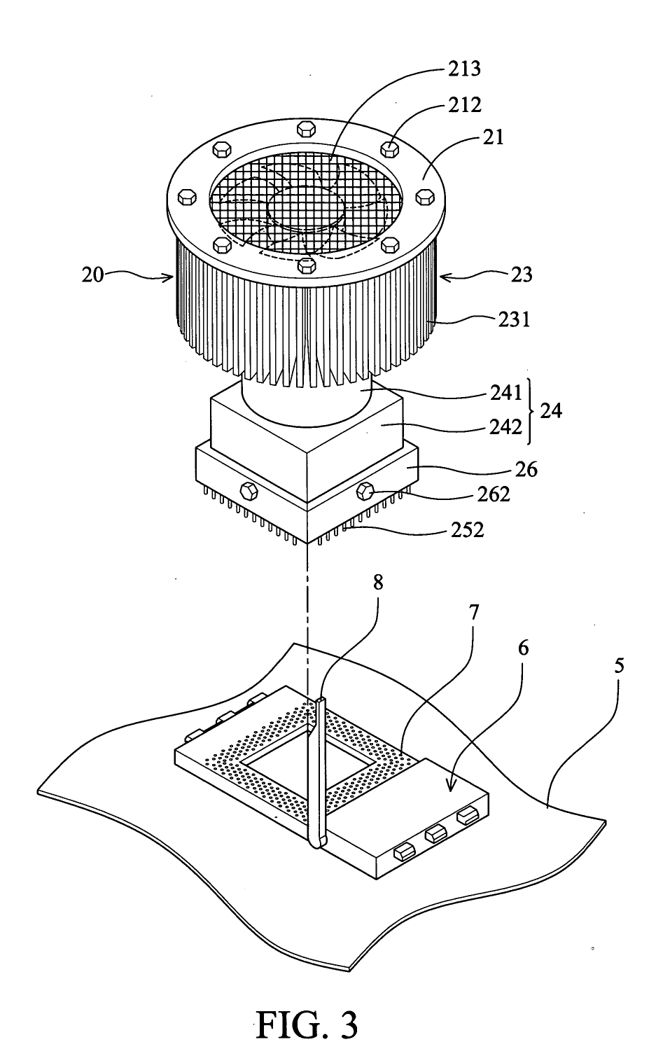

FIG. 3 shows the mount 20 for motherboard testing of the embodiment of the invention. In FIG. 3, because of the extending portion 24 (241, 242) of the heat sink 23 in this preferred embodiment, access is not limited during microprocessor installation. The extension pins 252 of the protecting port 25 (shown in FIG. 2) are easily aligned with the holes 7 of the protecting port 6 on the motherboard 5 to install the microprocessor 1 (shown in FIG. 2) thereon. Moreover, height of the extending portion 24 (241, 242) of the heat sink 23 is adjustable by means of the separated second part 242. Thus, the heat sink 23 will not interfere with the clip 8 of the protecting port 6 when installing the microprocessor.

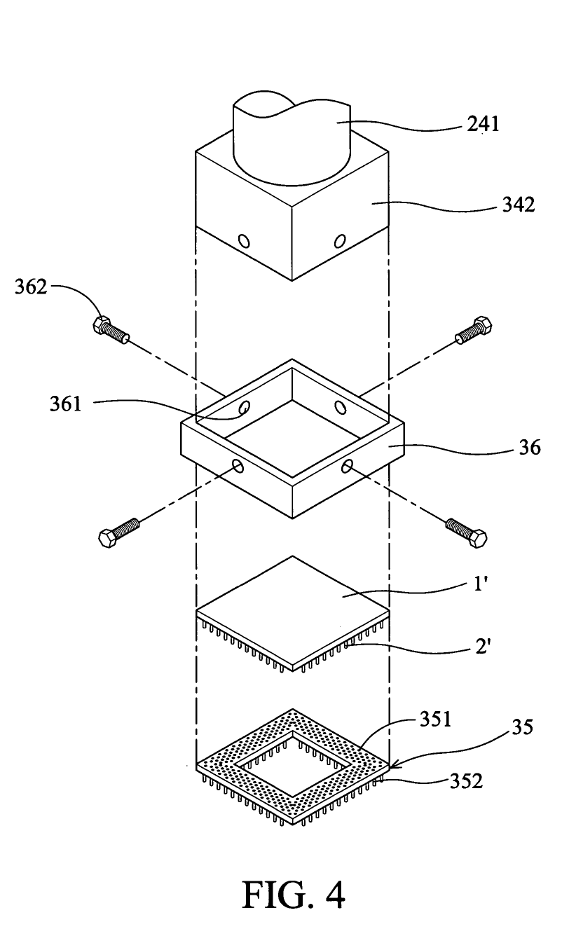

In FIG. 4, during installation of another microprocessor with equal or similar profile but different pin arrangement by the mount of the invention, a second protecting port 35 housing a second microprocessor 1′ can be easily applied. Similarly, the second protecting port 35 comprises a plurality of electrically connected second extension pins 352 and second holes 351 matching the second pins 2′ of the second microprocessor 1′.

By way of the removable second part 342 of the extending portion, alternate second part 342, frame 36 and protecting port 35 can be provided when required by a profile of the microprocessor 1′ being much larger than the first one in FIG. 2. Thus, the mount of the invention is compatible with different microprocessors and motherboards, providing increased flexibility.

Moreover, the heat sink 23 of the invention can have other shapes, such as a rectangle. The fins 231 are not limited to radial arrangement, and can be parallel. The heat sink can be a conventional rectangular heat sink with an extending portion to avoid restriction of access caused by the heat sink.

While the invention has been described by way of example and in terms of the preferred embodiment, it is acting as both understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A mount for use with a microprocessor with pins, comprising:
a heat sink with an extending portion; and
a protecting port removably disposed on the extending portion, wherein the protecting port comprises a plurality of electrically connected extension pins and holes, and the holes match the pins of the microprocessor.

2. The mount as claimed in claim 1, further comprising a frame fixing the protecting port to the extending portion.

3. The mount as claimed in claim 1, further comprising a fan mounted on the heat sink for heat dissipation.

4. The mount as claimed in claim 3, wherein the heat sink comprises a hollow protecting portion and a plurality of fins, the fan disposed in the hollow protecting portion.

5. The mount as claimed in claim 4, wherein the fins are radially arranged.

6. The mount as claimed in claim 4, wherein the hollow and the extending portion are located on opposite sides of the heat sink.

7. The mount as claimed in claim 5, wherein the extending portion comprises a first part and a removable second part.

8. The mount as claimed in claim 7, wherein the first part is cylindrical.

9. The mount as claimed in claim 7, wherein the second part is rectangular, with the frame removably disposed thereon.

10. The mount as claimed in claim 7, wherein the heat sink and the removable second part comprise aluminum and copper.

11. A mount for a first microprocessor with first pins or a second microprocessor with second pins, comprising:
a heat sink with an extending portion; and
a first protecting port for the first microprocessor; and
a second protecting port for the second microprocessor, wherein the first protecting port and the second protecting port are alternatively disposed on the extending portion.

12. The mount as claimed in claim 11, wherein the first protecting port comprises a plurality of electrically connected first extension pins and first holes, and the first holes match the first pins of the first microprocessor.

13. The mount as claimed in claim 11, wherein the second protecting port comprises a plurality of electrically connected second extension pins and second holes, and the second holes match the second pins of the second microprocessor.

14. The mount as claimed in claim 11, further comprising a frame fixing the first protecting port and the second protecting port alternatively on the extending portion.

15. The mount as claimed in claim 11, further comprising a fan mounted on the heat sink for heat dissipation.

16. The mount as claimed in claim 15, wherein the heat sink comprises a hollow protecting portion and a plurality of fins, and the fan is disposed in the hollow protecting portion.

17. The mount as claimed in claim 16, wherein the fins are radially arranged.

18. The mount as claimed in claim 16, wherein the hollow and the extending portion are located on opposite sides of the heat sink.

19. The mount as claimed in claim 17, wherein the extending portion comprises a first part and a removable second part.

20. The mount as claimed in claim 19, wherein the heat sink and the removable second part comprise aluminum and copper.

21. A mount for a microprocessor, comprising:
a heat sink with an extending portion;
a frame connecting the extending portion; and
a protecting port housing the microprocessor, removably disposed on the extending portion by the frame.

22. The mount as claimed in claim 21, further comprising a fan mounted on the heat sink for heat dissipation.
